(19) United States
(12) Patent Application Publication
(10) Pub. No.: US 2025/0126990 A1
(43) Pub. Date: Apr. 17, 2025

(54) Display Substrate and Preparation Method thereof, and Display Device

(71) Applicants: Yunnan Invensight Optoelectronics Technology Co., Ltd., Kunming, Yunnan (CN); BOE Technology Group Co., Ltd., Beijing (CN)

(72) Inventors: Chao PU, Beijing (CN); Shengji YANG, Beijing (CN); Xiaochuan CHEN, Beijing (CN); Kuanta HUANG, Beijing (CN); Pengcheng LU, Beijing (CN); Junbo WEI, Beijing (CN); Mingrui ZHANG, Beijing (CN); Zhao MA, Beijing (CN); Liuzeming QU, Beijing (CN)

(21) Appl. No.: 18/681,085

(22) PCT Filed: Aug. 19, 2022
(86) PCT No.: PCT/CN2022/113645

§ 371 Date: Feb. 5, 2024

(51) Int. Cl. H10K 59/131; H10K 59/12

(52) U.S. Cl. CPC H10K 59/131; H10K 59/1201

(57) ABSTRACT

Disclosed are a display substrate and preparation method thereof, and a display device. The display substrate includes a display area (100) and a bonding area (200). On a plane perpendicular to the display substrate, the bonding area (200) includes a base substrate (10), a bonding structure layer (70) disposed on the base substrate (10), and a bonding pad (80) disposed on the bonding structure layer (70). The bonding pad (80) is configured to be bonded to connect to a circuit board; and at least includes a first bonding pad layer (210) and a second bonding pad layer (220), the first bonding pad layer (210) is disposed on a side of the second bonding pad layer (220) away from the base substrate (10), at least one first concave-convex structure (310) is disposed on a surface of a side of the first bonding pad layer (210) away from the base substrate (10).

### CROSS-REFERENCE TO RELATED APPLICATION

The present application is a U.S. National Phase Entry of International Application No. PCT/CN2022/113645 having an international filing date of Aug. 19, 2022, the content of which is hereby incorporated by reference.

### TECHNICAL FIELD

The present disclosure relates to, but is not limited to, the field of display technologies, and in particular to a display substrate and a method for preparing a display substrate, and a display device.

### BACKGROUND

Micro organic light-emitting diodes (Micro OLEDs) are micro displays developed in recent years, among which there are silicon-based OLEDs. The silicon-based OLEDs can implement not only active addressing of pixels, but also manufacturing of structures, such as pixel driving circuits, on a silicon substrate, which is conducive to decrease system volume to implement lightweight. The silicon-based OLED, which is manufactured using mature complementary metal oxide semiconductor (CMOS) integrated circuit technologies, has advantages such as a small size, a high pixels per inch (PPI), and a high refresh rate.

### SUMMARY

The following is a summary of subject matter described herein in detail. The summary is not intended to limit the scope of protection of the claims.

The present disclosure provides a display substrate, including a display area and a bonding area located on a side of the display area, wherein on a plane perpendicular to the display substrate, the bonding area includes a base substrate, a bonding structure layer disposed on the base substrate, and a bonding pad disposed on a side of the bonding structure layer away from the base substrate, the bonding pad is configured to be bonded to connect to a circuit board; the bonding pad at least includes a first bonding pad layer and a second bonding pad layer, the first bonding pad layer is disposed on a side of the second bonding pad layer away from the base substrate, and at least one first concave-convex structure is disposed on a surface of a side of the first bonding pad layer away from the base substrate.

In an exemplary implementation, a reducibility of the first bonding pad layer is less than that of the second bonding pad layer.

In an exemplary implementation, a conductivity of the first bonding pad layer is less than that of the second bonding pad layer.

In an exemplary implementation, a surface roughness of a surface of a side of the first bonding pad layer away from the base substrate is greater than that of a surface of a side of the second bonding pad layer away from the base substrate.

In an exemplary implementation, a thickness of the first bonding pad layer is greater than that of the second bonding pad layer.

In an exemplary implementation, the first concave-convex structure includes at least one first protrusion and at least one first groove, there is a first distance between a first top on a side of the first protrusion away from the base substrate and a first bottom on a side of the first groove close to the base substrate, and the first distance is less than or equal to 0.5*a thickness of the first bonding pad layer.

In an exemplary implementation, the bonding area further includes a composite insulating layer disposed on a side of the bonding structure layer away from the base substrate, at least one pad groove is disposed on the composite insulating layer, and the first bonding pad layer and the second bonding pad layer are disposed in the pad groove.

In an exemplary implementation, the first concave-convex structure includes at least one first protrusion, there is a first height between a first top on a side of the first protrusion away from the base substrate and a surface of a side of the composite insulating layer close to the base substrate, and there is a second height between a surface of a side of the composite insulating layer away from the base substrate and the surface of the side of the composite insulating layer close to the base substrate, the first height is less than the second height.

In an exemplary implementation, there is a first junction line with between the first protrusion and a surface of a side of the first bonding pad layer away from the base substrate, the first junction line includes a junction point close to a side of the display area, and there is a first length between the junction point and a first sidewall, the first length is greater than or equal to 0.

In an exemplary implementation, the first length is smaller than or equal to a difference between the second height and the first height.

In an exemplary implementation, the bonding pad further includes a third bonding pad layer disposed between the first bonding pad layer and the second bonding pad layer, a conductivity of the third bonding pad layer is less than that of the first bonding pad layer, and a reducibility of the third bonding pad layer is less than that of the first bonding pad layer.

In an exemplary implementation, a thickness of the third bonding pad layer is less than or equal to 0.2*a thickness of the first bonding pad layer, and the thickness of the third bonding pad layer is less than or equal to 0.2*a thickness of the second bonding pad layer.

In an exemplary implementation, a surface roughness of a surface of a side of the third bonding pad layer away from the base substrate is less than that of a surface of a side of the first bonding pad layer away from the base substrate.

In an exemplary implementation, a surface roughness of a surface of a side of the third bonding pad layer away from the base substrate is less than that of a surface of a side of the second bonding pad layer close to the base substrate.

In an exemplary implementation, at least one third concave-convex structure is disposed on a surface of a side of the third bonding pad layer away from the base substrate.

In an exemplary implementation, the first concave-convex structure includes at least one first protrusion and at least one first groove, there is a first distance between a first top on a side of the first protrusion away from the base substrate and a first bottom on a side of the first groove close to the base substrate; the third concave-convex structure includes at least one third protrusion and at least one third groove, and there is a third distance between a third top on a side of the third protrusion away from the base substrate and a third bottom on a side of the third groove close to the base substrate; the third distance is less than the first distance.

In an exemplary implementation, at least one second concave-convex structure is disposed on a surface of a side of the second bonding pad layer close to the base substrate, the second concave-convex structure includes at least one second protrusion and at least one second groove, and there is a second distance between a second top on a side of the second protrusion close to the base substrate and a second bottom on a side of the second groove away from the base substrate; and the second distance is less than the first distance.

In an exemplary implementation, the display area includes a base substrate, a drive structure layer disposed on the base substrate, and a light emitting structure layer disposed on a side of the drive structure layer away from the base substrate; the light emitting structure layer at least includes an anode, the anode includes a first anode layer, a second anode layer disposed on a side of the first anode layer away from the base substrate, a third anode layer disposed on a side of the second anode layer away from the base substrate, and a fourth anode layer disposed on a side of the third anode layer away from the base substrate, the first bonding pad layer in the bonding pad is disposed in a same layer as the fourth anode layer, and the third bonding pad layer in the bonding pad is disposed in a same layer as the third anode layer.

In an exemplary implementation, a thickness of the fourth anode layer is less than that of the first bonding pad layer.

The present disclosure further provides a display device, including the display substrate describe above.

The present disclosure further provides a method for preparing a display substrate, the display substrate including a display area and a bonding area located at a side of the display area. The method includes: forming a bonding structure layer on a base substrate; and forming a bonding pad on the bonding structure layer, wherein the bonding pad is configured to be bonded to connect to a circuit board; the bonding pad at least includes a first bonding pad layer and a second bonding pad layer, the first bonding pad layer is disposed on a side of the second bonding pad layer away from the base substrate, and at least one first concave-convex structure is disposed on a surface of a side of the first bonding pad layer away from the base substrate.

After the drawings and the detailed descriptions are read and understood, the other aspects may be comprehended.

### BRIEF DESCRIPTION OF DRAWINGS

Accompanying drawings are intended to provide a further understanding of technical solutions of the present disclosure and form a part of the specification, and are used to explain the technical solutions of the present disclosure together with embodiments of the present disclosure, and do not form limitations on the technical solutions of the present disclosure. Shapes and sizes of various components in the drawings do not reflect actual scales, but are only intended to schematically illustrate contents of the present disclosure.

FIG. 1 is a schematic diagram of a structure of a silicon-based OLED display device.

FIG. 2 is a schematic plan view of a silicon-based OLED display substrate.

FIG. 3 is a schematic diagram of a planar structure of a display area in a silicon-based OLED display substrate.

FIG. 4 is a schematic diagram of a sectional structure of a display area in a silicon-based OLED display substrate.

FIG. 5 is a diagram of an equivalent circuit of a pixel drive circuit.

FIG. 6 is a schematic diagram of a structure of a display substrate according to an exemplary embodiment of the present disclosure.

FIG. 7 is a schematic diagram of a structure of a bonding pad according to an exemplary embodiment of the present disclosure.

FIG. 8 is a schematic diagram of a display substrate after patterns of a drive structure layer and a bonding structure layer are formed according to the present disclosure.

FIG. 9 is a schematic diagram of a structure of a second bonding electrode according to an exemplary embodiment of the present disclosure.

FIG. 10 is a schematic diagram of a display substrate after a pattern of a second bonding pad layer is formed according to the present disclosure.

FIG. 11 is a schematic diagram of a structure of a second bonding pad layer according to an exemplary embodiment of the present disclosure.

FIG. 12 is a schematic diagram of a display substrate after a pattern of a composite insulating layer is formed according to the present disclosure.

FIG. 13 is a schematic diagram of a display substrate after a pattern of an anode conductive post is formed according to the present disclosure.

FIG. 14 is a schematic diagram of a display substrate after patterns of a first anode layer and a second anode layer are formed according to the present disclosure.

FIG. 15 is a schematic diagram of a display substrate after patterns of a third anode layer, a fourth anode layer, a third bonding pad layer and a first bonding pad layer are formed according to the present disclosure.

FIG. 16 is a schematic diagram of a structure of a first bonding pad layer according to an exemplary embodiment of the present disclosure.

FIG. 17 is a schematic diagram of a display substrate after a pattern of a pixel definition layer is formed according to the present disclosure.

FIG. 18 is a schematic diagram of a display substrate after patterns of an organic light emitting layer and a cathode are formed according to the present disclosure.

FIG. 19 is a schematic diagram of a planar structure of a bonding pad in a bonding area of a display substrate of the present disclosure.

FIG. 20 is a sectional view taken in an A-A direction in FIG. 19.

FIG. 21 is a sectional view taken in a B-B direction in FIG. 19.

### REFERENCE SIGNS ARE DESCRIBED AS FOLLOWS

10—base substrate; 11—transistor; 12—composite insulating layer;
13—connection via; 14—anode conductive post; 20—drive structure layer;
30—light emitting structure layer; 31—anode; 31-1—first anode layer;
31-2—second anode layer; 31-3—third anode layer; 31-4—fourth anode layer;
32—pixel definition layer; 33—organic light emitting layer; 34—cathode;
40—encapsulation structure layer; 50—color filter structure layer; 60—cover plate structure layer;
70—bonding structure layer; 80—bonding pad; 90—pad groove;
100—display area; 200—bonding area; 201—first bonding electrode;
202—second bonding electrode; 210—first bonding pad layer; 220—second bonding pad layer;
230—third bonding pad layer; 300—bezel area; 310—first concave-convex structure;
320—second concave-convex structure; 330—third concave-convex structure.

### DETAILED DESCRIPTION

To make the objectives, technical solutions, and advantages of the present disclosure clearer, the embodiments of the present disclosure will be described in detail below in combination with the accompany drawings. It is to be noted that the implementations may be implemented in various forms. Those of ordinary skill in the art can easily understand such a fact that modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict. In order to keep following description of the embodiments of the present disclosure clear and concise, detailed description of part of known functions and known components is omitted in the present disclosure. The drawings of the embodiments of the present disclosure relate only to the structures involved in the embodiments of the present disclosure, and as to other structures, reference may be made to conventional designs.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. The quantity of pixels in a display device and the quantity of sub-pixels in each pixel are not limited to the quantity shown in the drawings. The drawings described in the present disclosure are schematic structure diagrams only, and one implementation of the present disclosure is not limited to the shapes or numerical values shown in the drawings.

Ordinal numerals “first”, “second”, “third”, etc., in the specification are set to avoid the confusion of composition elements rather than forming limits in quantity.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements with reference to the drawings, not to indicate or imply that involved devices or elements are required to have specific orientations and be structured and operated with the specific orientations but only to easily and simply describe the present specification, and thus should not be understood as limits to the present disclosure. The positional relationships between the composition elements may be changed as appropriate according to the direction where each composition element is described. Therefore, appropriate replacements based on situations are allowed, not limited to the expressions in the specification.

In the specification, unless otherwise specified and defined, terms “mounting”, “mutual connection”, and “connection” should be generally understood. For example, the term may be fixed connection, or detachable connection, or integral connection. The term may be mechanical connection or electric connection. The term may be direct connection, or indirect connection through an intermediate, or communication inside two elements. Those of ordinary skills in the art can understand the specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain electrode) and the source electrode (source electrode terminal, source region, or source electrode), and a current may flow through the drain electrode, the channel region, and the source region. In the specification, the channel region refers to a region through which a current mainly flows.

In the specification, in order to distinguish between two electrodes of the transistor except the gate electrode, one of the two electrodes is directly referred to as a first electrode and the other is referred to as a second electrode. The first electrode may be a drain electrode and the second electrode may be a source electrode, or the first electrode may be a source electrode and the second electrode may be a drain electrode. In cases that transistors with opposite polarities are used, or a current direction changes during work of a circuit, or the like, functions of the “source electrode” and the “drain electrode” may sometimes be exchanged. Therefore, the “source electrode” and the “drain electrode” may be exchanged in the specification.

In the specification, a “connection” includes a case where constitute elements are connected together through an element with some kind of electrical action. “An element with a certain electric action” is not particularly limited as long as electric signals between the connected composition elements may be sent and received. Examples of “an element with a certain electric action” not only include an electrode and a line, but also include a switch element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulating film” may be replaced with an “insulating layer” sometimes.

In the specification, “disposed in a same layer” refers to structures formed by patterning two (or more than two) structures through a same patterning process, and their materials may be the same or different. For example, materials of precursors for forming multiple structures disposed in a same layer are the same, and final materials may be the same or different.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present disclosure, “about” refers to that a boundary is not defined so strictly and numerical values within process and measurement error ranges are allowed.

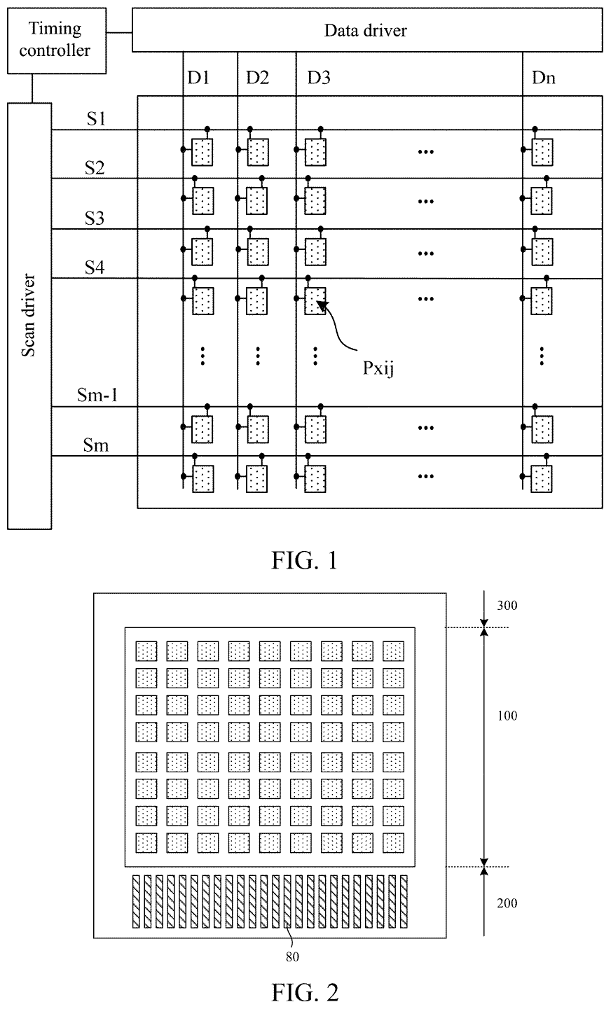

FIG. 1 is a schematic diagram of a structure of a silicon-based OLED display device. Referring to FIG. 1, the silicon-based OLED display device may include a timing controller, a data signal driver, a scan signal driver and a pixel array. The pixel array may include a plurality of scan signal lines (S1 to Sm), a plurality of data signal lines (D1 to Dn) and a plurality of sub-pixels Pxij. In an exemplary implementation, the timing controller may provide the data signal driver with a grayscale value and a control signal which are suitable for a specification of the data signal driver, and provide the scan signal driver with a clock signal, a scan start signal, and the like which are suitable for a specification of the scan signal driver. The data signal driver may generate data voltages to be provided to data signal lines D1, D2, D3, . . . , and Dn using the gray scale value and the control signal received from the timing controller. For example, the data signal driver may sample the grayscale values using the clock signal and apply the data voltages corresponding to the grayscale values to the data signal lines D1 to Dn by taking a row of sub-pixels as a unit, wherein n may be a natural number. The scan signal driver may generate scan signals to be provided to scan signal lines S1, S2, S3, . . . , and Sm by receiving a clock signal, a scan start signal, and the like from the timing controller. For example, the scan signal driver may sequentially provide scan signals with on-level pulses to the scan signal lines S1 to Sm. For example, the scan signal driver may be constructed in the form of a shift register, and generate the scan signals by sequentially transmitting the scan starting signals provided in the form of on-level pulses to a next-stage circuit under the control of the clock signal, wherein m may be a natural number. A sub-pixel array may include multiple sub-pixels PXij. Each sub-pixel PXij may be connected to a corresponding data signal line and a corresponding scan signal line, wherein i and j may be natural numbers. The sub-pixel Pxij may refer to a sub-pixel in which a transistor is connected to both the i-th scan signal line and the j-th data signal line.

FIG. 2 is a schematic plan view of a silicon-based OLED display substrate. As shown in FIG. 2, the silicon-based OLED display substrate may include a display area (AA area) 100, a bonding area 200 located on a side of the display area 100, and a bezel area 300 located on other sides of the display area 100. The display area 100 at least includes a plurality of sub-pixels arranged regularly, the bonding area 200 at least includes a bonding pad 80 configured to be bonded to connect to an external Flexible Printed Circuit (FPC), and the bezel area 300 at least includes a peripheral circuit configured to provide a drive signal to a pixel drive circuit in a sub-pixel.

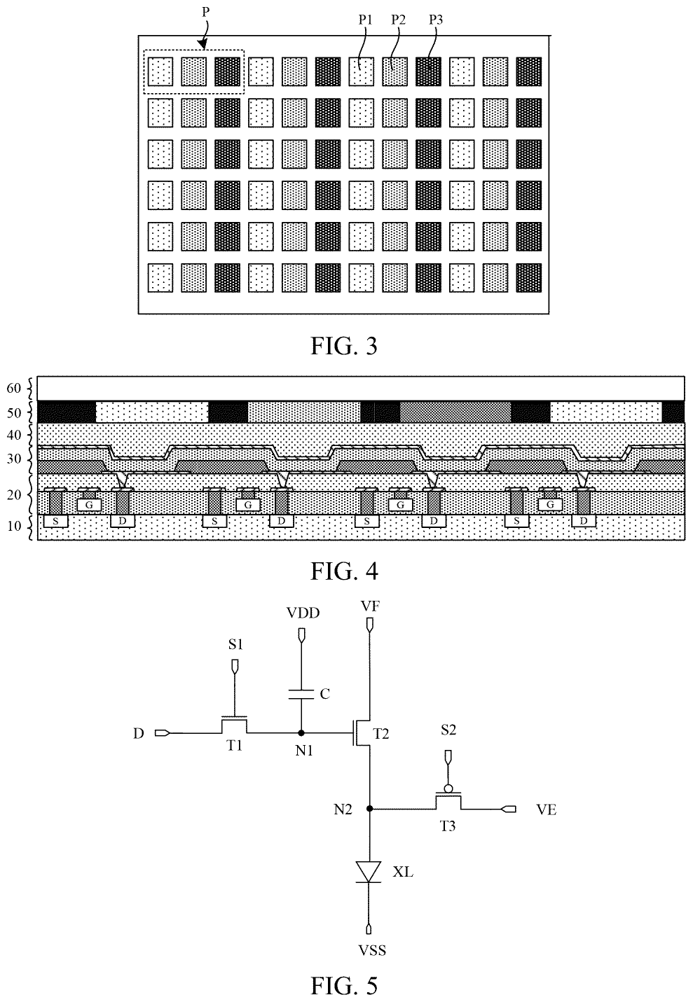

FIG. 3 is a schematic diagram of a planar structure of a display area in a silicon-based OLED display substrate. As shown in FIG. 3, the display area may include multiple pixel units P arranged in a matrix. At least one of the multiple pixel units P includes a first sub-pixel P1 emitting light of a first color, a second sub-pixel P2 emitting light of a second color, and a third sub-pixel P3 emitting light of a third color. The three sub-pixels each include a pixel drive circuit and a light emitting device. A pixel drive circuit in a sub-pixel is respectively connected to a scan signal line and a data signal line, and the pixel drive circuit is configured to receive a data voltage transmitted by the data signal line and output a corresponding current to the light emitting device, under the control of the scan signal line. The light emitting device in the sub-pixel is connected to a pixel drive circuit of a sub-pixel where the light emitting device is located, and is configured to emit light with a corresponding brightness in response to a current output by the pixel drive circuit of the sub-pixel where the light emitting device is located.

In an exemplary implementation, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. The sub-pixels may be in a shape of any one or more of a triangle, a square, a rectangle, a rhombus, a trapezoid, a parallelogram, a pentagon, a hexagon and other polygons. The three sub-pixels may be arranged side by side horizontally, side by side vertically or in a shape of the Chinese character “ [symbol] ”, and the present disclosure is not limited thereto.

In some other possible implementations, the pixel unit may include four sub-pixels, and the present disclosure is not limited thereto.

FIG. 4 is a schematic diagram of a sectional structure of a display area in a silicon-based OLED display substrate, which illustrates a structure in which full color is implemented in a manner of white light+color filters. As shown in FIG. 4, the display area may include: a base substrate 10, a drive structure layer 20 disposed on the base substrate 10, a light emitting structure layer 30 disposed on a side of the drive structure layer 20 away from the base substrate 10, an encapsulation structure layer 40 disposed on a side of the light emitting structure layer 30 away from the base substrate 10, a color filter structure layer 50 disposed on a side of the encapsulation structure layer 40 away from the base substrate 10, and a cover plate structure layer 60 disposed on a side of the color filter structure layer 50 away from the base substrate 10. In some possible implementations, the silicon-based OLED display device may include other film layers, and the present disclosure is not limited thereto.

In an exemplary implementation, the base substrate 10 may be a silicon substrate, also referred to as an IC wafer, and the silicon substrate may be a bulk silicon substrate or a Silicon-On-Insulator (SOI) substrate. The drive structure layer 20 may be prepared on the base substrate 10 by a silicon semiconductor process (e.g. a CMOS process) and may include a plurality of pixel drive circuits. A pixel drive circuit may include a plurality of transistors and a storage capacitor. FIG. 4 merely illustrates an example where the pixel drive circuit includes one transistor. The transistor may include a gate electrode G, a first electrode S and a second electrode D. The gate electrode G, the first electrode S and the second electrode D may be connected respectively to corresponding connection electrodes through vias filled with tungsten metal (i.e., tungsten via, W-via), and may be connected to other electrical structures (e.g., traces) through the connection electrodes.

In an exemplary implementation, the light emitting structure layer 30 may include a plurality of light emitting devices, and a light emitting device may at least include an anode, an organic light emitting layer and a cathode. The anode may be connected to the second electrode D of the transistor through a connection electrode, the organic light emitting layer is connected to the anode, the cathode is connected to the organic light emitting layer, and the cathode is connected to a second power supply line. The organic light emitting layer emits light under the driving of the anode and the cathode. In an exemplary implementation, the organic light emitting layer may include an Emitting Layer (EML) and any one or more of a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation, for a light emitting device emitting white light, organic light emitting layers of all sub-pixels may be connected together to form a common layer.

In an exemplary implementation, the encapsulation structure layer 40 may adopt a Thin Film Encapsulation (TFE) mode, so as to ensure that external water vapor cannot enter the light emitting structure layer. The cover plate structure layer 60 may be made of glass, or plastic colorless polyimide having flexible characteristics, etc.

In an exemplary implementation, the color filter structure layer 50 may include a black matrix (BM) and color filters (CFs). The color filters are provided in red (R) sub-pixels, green (G) sub-pixels and blue (B) sub-pixels respectively, and filter white light emitted by the light emitting devices into red (R) light, green (G) light and blue (B) light. The black matrix may be located between adjacent color filters.

FIG. 5 is a diagram of an equivalent circuit of a pixel drive circuit. In an exemplary implementation, the pixel drive circuit may be in a structure of 3T1C, 4T1C, 5T1C, 5T2C, 6T1C, 7T1C or the like. As shown in FIG. 4, the pixel drive circuit may be a structure of 3T1C, which includes three transistors (a first transistor T1, a second transistor T2 and a third transistor T3) and one storage capacitor C. The pixel drive circuit is connected to seven signal lines (a first scan signal line S1, a second scan signal line S2, a data signal line D, a reference signal line VE, a first power supply line VDD and a light emitting voltage line VF). A first node N1 and a second node N2 are junction points that represent relevant electrical connections in the circuit diagram.

In an exemplary implementation, a first terminal of the storage capacitor C may be connected to the first node N1, and a second terminal of the storage capacitor C may be connected to the first power supply line VDD.

In an exemplary implementation, a gate electrode of the first transistor T1 is connected to a first scan signal line S1, a first electrode of the first transistor T1 is connected to the data signal line D, and a second electrode of the first transistor T1 is connected to the first node N1.

In an exemplary implementation, a gate electrode of the second transistor T2 is connected to the first node N1, a first electrode of the second transistor T2 is connected to a light emitting voltage line VF, and a second electrode of the second transistor T2 is connected to the second node N2.

In an exemplary implementation, a gate electrode of the third transistor T3 is connected to a second scan signal line S2, a first electrode of the third transistor T3 is connected to a reference signal line VE, and a second electrode of the third transistor T3 is connected to the second node N2.

In an exemplary implementation, a first electrode of a light emitting device XL is connected to the second node N2, and a second electrode of the light emitting device XL is connected to a second power supply line VSS.

In an exemplary implementation, the first transistor T1 is configured to, under the control of a signal of the first scan signal line S1, receive a data voltage transmitted by the data signal line D, store the data voltage into the storage capacitor C, and provide the data voltage to the gate electrode of the second transistor T2. The second transistor T2 is configured to, under the control of the data signal received by its gate electrode, generate a corresponding current at its second electrode to drive the display light emitting device XL to emit light. The third transistor T3 is configured to, under the control of a signal of the second scan signal line S2, receive a reference voltage transmitted by the reference signal line VE and provide the reference voltage to the second node N2. The storage capacitor C is configured to store a potential of the gate electrode of the second transistor T2. The light emitting device XL is configured to emit light with a corresponding brightness in response to the current of the second electrode of the second transistor T2.

In an exemplary implementation, a signal of the first power supply line VDD may be a high-level signals continuously provided, a signal of the light emitting voltage line VF may be a voltage signal output by a light emitting control transistor, and a signal of the second power supply line VSS may be a low-level signal continuously provided.

In an exemplary implementation, the first transistor T1, the second transistor T2 and the third transistor T3 may be P-type transistors. In another exemplary implementation, the first transistor T1, the second transistor T2, and the third transistor T3 may be N-type transistors. Usage of a same type of transistors in a pixel drive circuit may simplify a process flow, reduce a process difficulty of a display panel, and improve a product yield. In yet another exemplary implementation, the first transistor T1, the second transistor T2 and the third transistor T3 may include P-type transistor(s) and N-type transistor(s). For example, the first transistor T1 and the third transistor T3 may be P-type metal oxide semiconductor (PMOS) transistors, and the second transistor T2 may be an N-type metal oxide semiconductor (NMOS) transistor.

In an exemplary implementation, the light emitting device XL may be an organic light emitting diode (OLED), including a first electrode (anode), an organic light emitting layer and a second electrode (cathode) that are stacked.

At present, a method for preparing a silicon-based OLED display substrate includes: preparing a plurality of display substrates on a display motherboard, wherein a display substrate includes an encapsulation layer covering a display area, bonding pads of a bonding area 200 are exposed; then, cutting the display motherboard into a plurality of separate display substrates, and then bonding a circuit board to a bonding pad through an Anisotropic Conductive Film (ACF). In the bonding process, it is needed that conductive auric balls (Au balls) in the anisotropic conductive film are in contact with gold fingers and the bonding pads of the circuit board respectively, and the conductive auric balls are broken by pressing to realize electrical connection between the gold fingers and the bonding pads. Studies have shown that due to severe corrosion of the exposed bonding pads, the bonding impedance increases, so the existing silicon-based OLED display substrates have the problem of poor bonding connection reliability, which negatively affects the reliability of silicon-based OLED display devices very much. Further studies have shown that the corrosion of the bonding pads is caused by the reaction of Cl₂ or Cl ions in an etching solution and bonding electrodes (such as Al) in the subsequent preparation process.

The present disclosure provides a silicon-based OLED display substrate, including a display area, and a bonding area located on a side of the display area, wherein on a plane perpendicular to the display substrate, the bonding area includes a base substrate, a bonding structure layer disposed on the base substrate, and a bonding pad disposed on a side of the bonding structure layer away from the base substrate, and the bonding pad is configured to be bonded to connect to a circuit board. The bonding pad at least includes a first bonding pad layer and a second bonding pad layer, the first bonding pad layer is disposed on a side of the second bonding pad layer away from the base substrate, and at least one first concave-convex structure is disposed on a surface of a side of the first bonding pad layer away from the base substrate.

In an exemplary implementation, the bonding pad further includes a third bonding pad layer disposed between the first bonding pad layer and the second bonding pad layer, a conductivity of the first bonding pad layer is less than that of the second bonding pad layer, and a conductivity of the third bonding pad layer is less than that of the first bonding pad layer.

In an exemplary implementation, at least one second concave-convex structure is disposed on a surface of a side of the second bonding pad layer close to the base substrate.

In an exemplary implementation, at least one third concave-convex structure is disposed on a surface of a side of the third bonding pad layer away from the base substrate.

In an exemplary implementation, the display area includes a base substrate, a drive structure layer disposed on the base substrate, and a light emitting structure layer disposed on a side of the drive structure layer away from the base substrate; the light emitting structure layer at least includes an anode, the anode includes a first anode layer, a second anode layer disposed on a side of the first anode layer away from the base substrate, a third anode layer disposed on a side of the second anode layer away from the base substrate, and a fourth anode layer disposed on a side of the third anode layer away from the base substrate, the first bonding pad layer is disposed in a same layer as a fourth anode layer, and the third bonding pad layer is disposed in a same layer as a third anode layer.

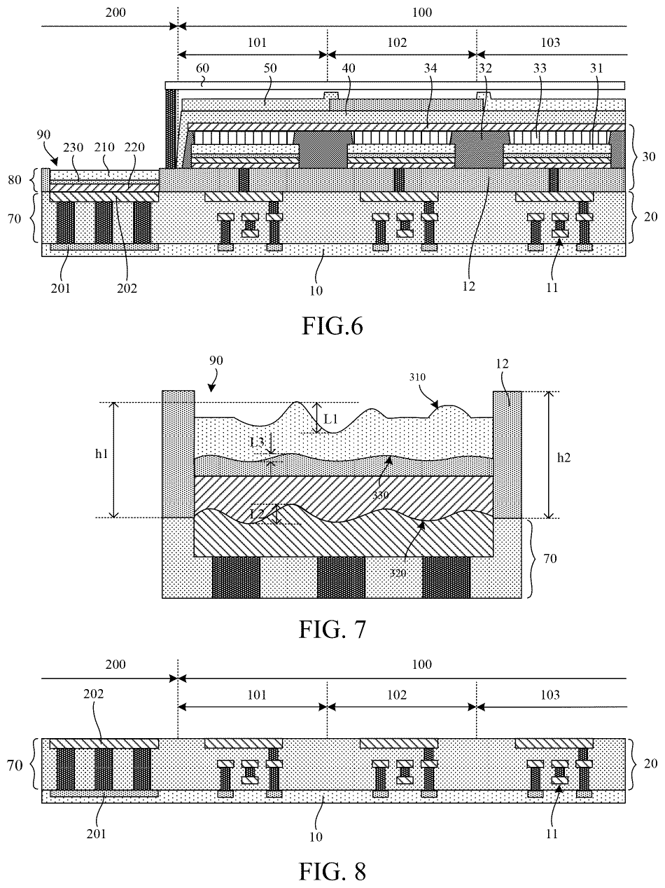

FIG. 6 is a schematic diagram of a structure of a display substrate according to an exemplary embodiment of the present disclosure, illustrating a structure in which full color display is achieved in a manner of white light+color filters. As shown in FIG. 6, the display substrate at least includes a display area 100 and a bonding area 200 located on a side of the display area 100. The display area 100 at least includes a plurality of sub-pixels arranged regularly, and the plurality of sub-pixels are configured to perform image display. The bonding area 200 at least includes a bonding pad configured to be bonded to connect to a circuit board (e.g., a flexible printed circuit). In a plane perpendicular to the display substrate, the display area 100 of the display substrate may include a base substrate 10, a drive structure layer 20 disposed on the base substrate 10, a light emitting structure layer 30 disposed on a side of the drive structure layer 20 away from the base substrate 10, an encapsulation structure layer 40 disposed on a side of the light emitting structure layer 30 away from the base substrate 10, a color filter structure layer 50 disposed on a side of the encapsulation structure layer 40 away from the base substrate 10, and a cover plate structure layer 60 disposed on a side of the color filter structure layer 50 away from the base substrate 10. In a plane perpendicular to the display substrate, the bonding area 200 of the display substrate may include a base substrate 10, a bonding structure layer 70 disposed on the base substrate 10, and a bonding pad 80 disposed on a side of the bonding structure layer 70 away from the base substrate 10.

In an exemplary implementation, the drive structure layer 20 of each sub-pixel in the display area 100 may include a plurality of pixel drive circuits, and the pixel drive circuit may be a structure of 3T1C, 4T1C, 5T1C, 5T2C, 6T1C, 7T1C or the like, or may be a circuit structure having an internal compensation or external compensation function. FIG. 6 merely illustrates an example in which the pixel drive circuit of one sub-pixel includes one transistor 11. The pixel drive circuit is respectively connected to a scan signal line, a data signal line and a first power supply line. The scan signal line is configured to provide a scan signal to the pixel drive circuit, the data signal line is configured to provide a data signal to the pixel drive circuit, and the first power supply line is configured to provide a power supply signal to the pixel drive circuit.

In an exemplary implementation, the light emitting structure layer 30 of each sub-pixel in the display area 100 may include a composite insulating layer 12 disposed on a side of the drive structure layer 20 away from the base substrate 10, a light emitting device disposed on a side of the composite insulating layer 12 away from the base substrate 10, and a pixel definition layer 32. The light emitting device may include an anode 31, an organic light emitting layer 33, and a cathode 34. The anode 31 is connected to the transistor 11 through a conductive post penetrating the composite insulating layer 12.

In an exemplary implementation, the anode 31 may at least include a first anode layer, a second anode layer disposed on a side of the first anode layer away from the base substrate, a third anode layer disposed on a side of the second anode layer away from the base substrate, and a fourth anode layer disposed on a side of the third anode layer away from the base substrate.

In an exemplary implementation, the encapsulation structure layer 40 of the display area 100 covers the display area 100. The color filter structure layer 50 is disposed on the encapsulation structure layer 40, and includes a first color unit corresponding to the first sub-pixel 101, a second color unit corresponding to the second sub-pixel 102, and a third color unit corresponding to the third sub-pixel 103. The cover plate structure layer 60 is disposed above the color filter structure layer 50, and is fixed by a sealant. The cover plate structure layer 60 can protect the color filter structure layer 50, and block water and oxygen from intruding into the light emitting structure layer 30, so as to prolong the service life of the silicon-based OLED display substrate.

In an exemplary implementation, the bonding structure layer 70 of the bonding area 200 may at least include a first bonding electrode 201 and a second bonding electrode 202. The second bonding electrode 202 is disposed on a side of the first bonding electrode 201 away from the base substrate, and the second bonding electrode 202 may be connected to the first bonding electrode 201 through a conductive post penetrating a plurality of insulating layers.

In an exemplary implementation, the bonding pad 80 of the bonding area 200 may at least include a second bonding pad layer 220, a third bonding pad layer 230 and a first bonding pad layer 210 that are stacked. The second bonding pad layer 220 is disposed on a side of the second bonding electrode 202 away from the base substrate in the bonding structure layer 70 and lapped with the second bonding electrode 202. The third bonding pad layer 230 is disposed on a side of the second bonding pad layer 220 away from the base substrate and lapped with the second bonding pad layer 220. The first bonding pad layer 210 is disposed on a side of the third bonding pad layer 230 away from the base substrate and lapped with the third bonding pad layer 230.

In an exemplary implementation, the first bonding pad layer 210 of the bonding area 200 and the fourth anode layer of the display area may be disposed in a same layer, and formed synchronously through a same patterning process, and the third bonding pad layer 230 of the bonding area 200 and the third anode layer of the display area may be disposed in a same layer and formed synchronously through a same patterning process.

In an exemplary implementation, a thickness of the fourth anode layer of the display area may be less than that of the first bonding pad layer 210 of the bonding area 200.

In an exemplary implementation, the bonding area 200 may further include a composite insulating layer 12 disposed on a side of the bonding structure layer 70 away from the base substrate, at least one pad groove 90 is disposed on the composite insulating layer 12, and the second bonding pad layer 220, the third bonding pad layer 230 and the first bonding pad layer 210 may be disposed in the pad groove 90.

In an exemplary implementation, the reducibility of the first bonding pad layer 210 may be less than that of the second bonding pad layer 220, and the reducibility of the third bonding pad layer 230 may be less than that of the first bonding pad layer 210.

In an exemplary implementation, the conductivity of the first bonding pad layer 210 may be less than that of the second bonding pad layer 220, and the conductivity of the third bonding pad layer 230 may be less than that of the first bonding pad layer 210.

In an exemplary implementation, surface roughness of a surface of a side of the first bonding pad layer 210 away from the base substrate may be greater than that of a surface of a side of the second bonding pad layer 220 away from the base substrate, the surface roughness of the surface of the side of the first bonding pad layer 210 away from the base substrate may be greater than that of a surface of a side of the third bonding pad layer 230 away from the base substrate, and surface roughness of a surface of a side of the second bonding pad layer 220 close to the base substrate may be greater than that of the surface of the side of the third bonding pad layer 230 away from the base substrate.

In an exemplary implementation, the thickness of the first bonding pad layer 210 may be greater than that of the second bonding pad layer 220, the thickness of the third bonding pad layer 230 may be less than or equal to 0.2*the thickness of the first bonding pad layer 210, and the thickness of the third bonding pad layer 230 may be less than or equal to 0.2*the thickness of the second bonding pad layer 220.

FIG. 7 is a schematic diagram of a structure of a bonding pad according to an exemplary embodiment of the present disclosure. As shown in FIG. 7, the bonding area 200 may include a composite insulating layer 12 disposed on the bonding structure layer 70, at least one pad groove 90 is disposed on the composite insulating layer 12, and the second bonding pad layer 220, the third bonding pad layer 230 and the first bonding pad layer 210 that form the bonding pad are disposed in the pad groove 90.

In an exemplary implementation, at least one first concave-convex structure 310 is disposed on a surface of a side of the first bonding pad layer 210 away from the base substrate.

In an exemplary implementation, the first concave-convex structure 310 may include at least one first protrusion and at least one first groove, there is a first distance L1 between a first top of a side of the first protrusion away from the base substrate and a first bottom of a side of the first groove close to the base substrate, and the first distance L1 may be less than or equal to 0.5*the thickness of the first bonding pad layer 310.

In an exemplary implementation, there is a first height h1 between a first top of a side of at least one first protrusion away from the base substrate and a surface of a side of the composite insulating layer 12 close to the base substrate, there is a second height h2 between a surface of a side of the composite insulating layer 12 away from the base substrate and the surface of the side of the composite insulating layer 12 close to the base substrate, and the first height h1 may be less than the second height h2.

In an exemplary implementation, at least one second concave-convex structure 320 is disposed on a surface of a side of the second bonding pad layer 220 close to the base substrate.

In an exemplary implementation, the second concave-convex structure 320 may include at least one second protrusion and at least one second groove, there is a second distance L2 between a second top of a side of the second protrusion close to the base substrate and a second bottom of a side of the second groove away from the base substrate, and the second distance L2 may be less than the first distance L1.

In an exemplary implementation, at least one third concave-convex structure 330 may be disposed on a surface of a side of the third bonding pad layer 230 away from the base substrate.

In an exemplary implementation, the third concave-convex structure 330 may include at least one third protrusion and at least one third groove, there is a third distance L3 between a third top of a side of the third protrusion away from the base substrate and a third bottom of a side of the third groove close to the base substrate, and the third distance L3 may be less than the first distance L1.

Exemplary description is made below through a preparation process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation and chemical vapor deposition, the coating may be any one or more of spray coating, spin coating and inkjet printing, and the etching may be any one or more of dry etching and wet etching, the present disclosure is not limited thereto. A “thin film” refers to a layer of thin film made of a certain material on a substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film layer is a size of the film layer in a direction perpendicular to a display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is coincided with the boundary of the orthographic projection of B.

In an exemplary implementation, the preparation process of the display substrate may include following operations.
(1) Patterns of a drive structure layer and a bonding structure layer are formed. In an exemplary implementation, the display substrate may include a display area 100 and a bonding area 200 disposed on a side of the display area 100. The display area 100 may include a plurality of sub-pixels, a pixel drive circuit is formed in a drive structure layer of each sub-pixel, and a bonding electrode is formed in a bonding structure layer of the bonding area 200.

In an exemplary implementation, the pixel drive circuit of each sub-pixel may adopt the 3T1C structure shown in FIG. 5, and a process of forming the patterns of the drive structure layer and the bonding structure layer may include the following a-o.
a. Providing a base substrate 10. The base substrate 10 may be made of a P-type silicon material or an N-type silicon material, the P-type silicon material may be used as a channel region of an N-type transistor, and the N-type silicon material may be used as a channel region of a P-type transistor.
b. Forming a first insulating layer that covers the base substrate 10 and a pattern of a polysilicon layer disposed on the first insulating layer by a patterning process, and performing a doping process using the pattern of the polysilicon layer as a shade to form patterns of a first conductive layer and an active layer. The pattern of the active layer may at least include a first active layer of a first transistor, a second active layer of a second transistor and a third active layer of a third transistor, and the pattern of the first conductive layer may at least include a first gate electrode of the first transistor, a second gate electrode of the second transistor and a third gate electrode of the third transistor.
c. Forming a second insulating layer that covers the patterns of the first conductive layer and the active layer and has a plurality of vias by a patterning process.
d. Forming a pattern of a second conductive layer on the second insulating layer by a patterning process. The pattern of the second conductive layer may at least include a first scan signal line, a second scan signal line and a plurality of connection electrodes, and the second conductive layer may be referred to as a first metal (Metal1) layer.
e. Forming a third insulating layer that covers the pattern of the second conductive layer and has a plurality of vias by a patterning process.
f. Forming a pattern of a third conductive layer on the third insulating layer by a patterning process. The pattern of the third conductive layer may at least include a data signal line, a reference signal line and a plurality of connection electrodes, and the third conductive layer may be referred to as a second metal (Metal2) layer.
g. Forming a fourth insulating layer that covers the pattern of the third conductive layer and has a plurality of vias by a patterning process.
h. Forming a pattern of a fourth conductive layer on the fourth insulating layer by a patterning process. The pattern of the fourth conductive layer may at least include a plurality of connection electrodes, and the fourth conductive layer may be referred to as a third metal (Metal3) layer.
i. Forming a fifth insulating layer that covers the pattern of the fourth conductive layer and has a plurality of vias by a patterning process.
j. Form a pattern of a fifth conductive layer on the fifth insulating layer by a patterning process. The pattern of the fifth conductive layer may at least include a plurality of connection electrodes, and the fifth conductive layer may be referred to as a fourth metal (Metal4) layer.
k. Forming a sixth insulating layer that covers the pattern of the fifth conductive layer and has a plurality of vias by a patterning process.
l. Forming a pattern of a sixth conductive layer on the sixth insulating layer by a patterning process. The pattern of the sixth conductive layer may at least include a first plate of a storage capacitor and a plurality of connection electrodes.
m. Forming a seventh insulating layer, that covers the pattern of the sixth conductive layer, and a pattern of a seventh conductive layer disposed on the seventh insulating layer by a patterning process. The pattern of the seventh conductive layer may at least include a second plate of the storage capacitor, and the seventh conductive layer may be referred to as a Metal-Insulator-Metal (MIM) layer.
n. Forming an eighth insulating layer that covers the pattern of the sixth conductive layer and has a plurality of vias by a patterning process.
o. Forming a pattern of an eighth conductive layer on the eighth insulating layer by a patterning process. The pattern of the eighth conductive layer may at least include an anodic connection electrode and a first power supply line, and the eighth conductive layer may be referred to as a Top Metal layer.

In an exemplary implementation, the pattern of the first conductive layer formed above may further include a first bonding electrode 201 located in the bonding area 200, the pattern of the eighth conductive layer formed may further include a second bonding electrode 202 located in the bonding area 200, the second bonding electrode 202 is connected to the first bonding electrode 201 through a plurality of conductive posts, and the first bonding electrode 201 and the second bonding electrode 202 form a bonding electrode of the bonding structure layer.

In an exemplary implementation, the first bonding electrode 201 may be located in the second conductive layer, the third conductive layer, the fourth conductive layer, the fifth conductive layer or the sixth conductive layer, or at least one of the second to sixth conductive layers may include at least one connection electrode through which the second bonding electrode 202 is connected to the first bonding electrode 201, the present disclosure is not limited thereto.

So far, the drive structure layer 20 and the bonding structure layer 70 have been prepared, as shown in FIG. 8. The drive structure layer 20 of the display area 100 may at least include a plurality of pixel drive circuits, and the bonding structure layer 70 of the bonding area 200 may at least include a plurality of bonding electrodes. In the display area 100 in FIG. 8, only a first sub-pixel 101, a second sub-pixel 102 and a third sub-pixel 103 are shown, and only one transistor 11 is shown in the pixel drive circuit in each sub-pixel, and only one first bonding electrode 201 and one second bonding electrode 202 are shown as the bonding electrodes in the bonding area 200.

In an exemplary implementation, a material of the base substrate may include any one or more of silicon, germanium and a compound semiconductor. The compound semiconductor may include any one or more of silicon germanium, silicon carbide, gallium arsenide, gallium phosphide, indium phosphide, indium arsenide and indium antimonide. The first to eighth insulating layers may be made of silicon oxide (SiOx), silicon nitride (SiNx), silicon oxynitride (SiON) or the like, and may have a single-layer structure or a multi-layer composite structure. The first to sixth metal layers may be made of a metal material, such as silver (Ag), copper (Cu), aluminum (Al), titanium (Ti), molybdenum (Mo), or the like, or may be made of an alloy material composed of metals, such as an aluminum-neodymium alloy (AlNd), a molybdenum-niobium alloy (MoNb), or the like, and the alloy material may be a single-layer structure or a multi-layer composite structure.

In an exemplary implementation, the first plate of the storage capacitor may be referred to as Capacity Bottom Metal (CBM), and the second plate of the storage capacitor may be referred to as Capacity Top Metal (CTM). An orthographic projection of the first plate on the base substrate at least partially overlaps an orthographic projection of the second plate on the base substrate. The first plate and the second plate form a storage capacitor of a MIM capacitor structure.

In an exemplary implementation, the top metal layer (the second bonding electrode) may include a titanium nitride (TiN) layer, an aluminum-copper (AlCu) layer and a titanium nitride layer that are stacked. The titanium nitride layer may help the aluminum-copper layer to adhere to the eighth insulating layer. The eighth insulating layer may adopt a SiO₂ layer and a Si₃N₄ layer that are stacked. The Si₃N₄ layer may play the role of insulation, preventing pollution, preventing mechanical damage, etc., and the SiO₂ layer may play the role of insulation, balancing the stress of the Si₃N₄ layer, flattening surfaces of the film layers, etc.

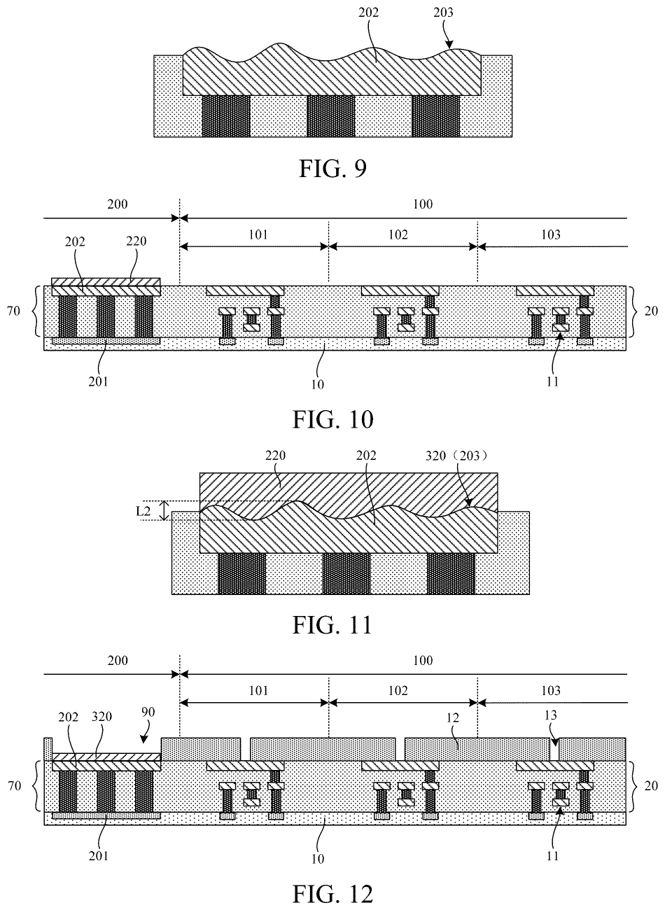

FIG. 9 is a schematic diagram of a structure of a second bonding electrode according to an exemplary embodiment of the present disclosure. As shown in FIG. 9, at least one electrode concave-convex structure 203 is formed on a surface of a side of the second bonding electrode 202 away from the base substrate, and the electrode concave-convex structure 203 may include at least one protrusion and at least one groove. In the present disclosure, by forming an electrode concave-convex structure on the surface of the side of the second bonding electrode 202 away from the base substrate, the contact area between the second bonding electrode 202 and the second bonding pad layer subsequently formed can be increased, and the reliability of electrical connection can be improved.
(2) A pattern of the second bonding pad layer is formed. In an exemplary implementation, forming the pattern of the second bonding pad layer may include: depositing a pad metal thin film on the base substrate on which the aforementioned patterns are formed, and patterning the pad metal thin film by a patterning process, to form the second bonding pad layer 220 in the bonding area 200, the second bonding pad layer 220 is lapped with the second bonding electrode 202, as shown in FIG. 10.

In an exemplary implementation, an orthographic projection of the second bonding pad layer 220 on the base substrate 10 may include an orthographic projection of the second bonding electrode 202 on the base substrate 10. For example, the orthographic projection of the second bonding pad layer 220 on the base substrate 10 may substantially coincide with the orthographic projection of the second bonding electrode 202 on the base substrate 10.

In an exemplary implementation, a material of the second bonding pad layer 220 may be a metal material of high conductivity, such as copper (Cu) or aluminum (Al). Conductivity is a measurement that represents the capability of a substance to transmit a current. Conductivity is the reciprocal of resistance. The greater the conductivity of a metal, the smaller the resistance of the metal.

In an exemplary implementation, the material of the second bonding pad layer 220 may be a metal material with high reducibility, such as copper (Cu) or aluminum (Al). Reducibility (also called metal reactivity) refers to the degree of reactivity of a metal in a chemical reaction, and reactive metals themselves tend to lose electrons and be subjected to oxidation reactions.

FIG. 11 is a schematic diagram of a structure of a second bonding pad layer according to an exemplary embodiment of the present disclosure. As shown in FIG. 11, a surface of a side of the second bonding pad layer 220 close to the base substrate is attached to a surface of a side of the second bonding electrode 202 away from the base substrate, and the surface of the side of the second bonding electrode 202 away from the base substrate is formed with at least one electrode concave-convex structure 203, thereby the surface of the side of the second bonding pad layer 220 close to the base substrate is formed with at least one second concave-convex structure 320 having a shape complementary to that of the electrode concave-convex structure 203. In the present disclosure, by disposing concave-convex structures on the surfaces where the second bonding electrode 202 and the second bonding pad layer 220 are attached to each other, the contact area between the second bonding electrode 202 and the second bonding pad layer 220 can be increased, and the reliability of electrical connection can be improved.

In an exemplary implementation, the second concave-convex structure 320 may include at least one second protrusion and at least one second groove, and there is a second distance L2 between the highest second top of the plurality of second protrusions on a side close to the base substrate 10 and the lowest second bottom of the plurality of second grooves on a side away from the base substrate 10.

In an exemplary implementation, the second concave-convex structure may be only a plurality of second protrusions provided on a flat surface, the second protrusions are higher than the flat surface, i.e., the thicknesses at the second protrusions are greater than the thickness of the flat surface, and which are between adjacent second protrusions are considered as second grooves. In another exemplary implementation, the second concave-convex structure may be only a plurality of second grooves provided on a flat surface, the second grooves are lower than the flat surface, i.e., the thicknesses at the second grooves are less than the thickness of the flat surface, and which are between adjacent second grooves are considered as second protrusions. In yet another exemplary implementation, the second concave-convex structure may be a plurality of second protrusions and a plurality of second grooves provided on a flat surface, the second protrusions are higher than the flat surface, and the second grooves are lower than the flat surface.
(3) A pattern of a composite insulating layer is formed. In an exemplary implementation, forming the pattern of the composite insulating layer may include: depositing a composite insulating thin film on the base substrate on which the above patterns are formed, and patterning the composite insulating thin film by a patterning process, to form a composite insulating layer 12 covering the display area 100 and the bonding area 200, wherein the composite insulating layer 12 in the display area 100 is formed with a plurality of connection vias 13, and the composite insulating layer 12 in the bonding area 200 is formed with at least one pad groove 90, as shown in FIG. 12.

In an exemplary implementation, the plurality of connection vias 13 in the display area 100 each may be respectively located in each sub-pixel. A composite insulating thin film in a connection via 13 is etched away to expose a surface of an anode connection electrode, and the connection via 13 is configured to accommodate an anode conductive post.

In an exemplary implementation, the pad groove 90 in the bonding area 200 may be located in an area where the second bonding pad layer 220 is located, and the composite insulating thin film in the pad groove 90 is etched away, to expose a surface of the second bonding pad layer 220.

In an exemplary implementation, an orthographic projection of the pad groove 90 on the base substrate may include an orthographic projection of the second bonding pad layer 220 on the base substrate.

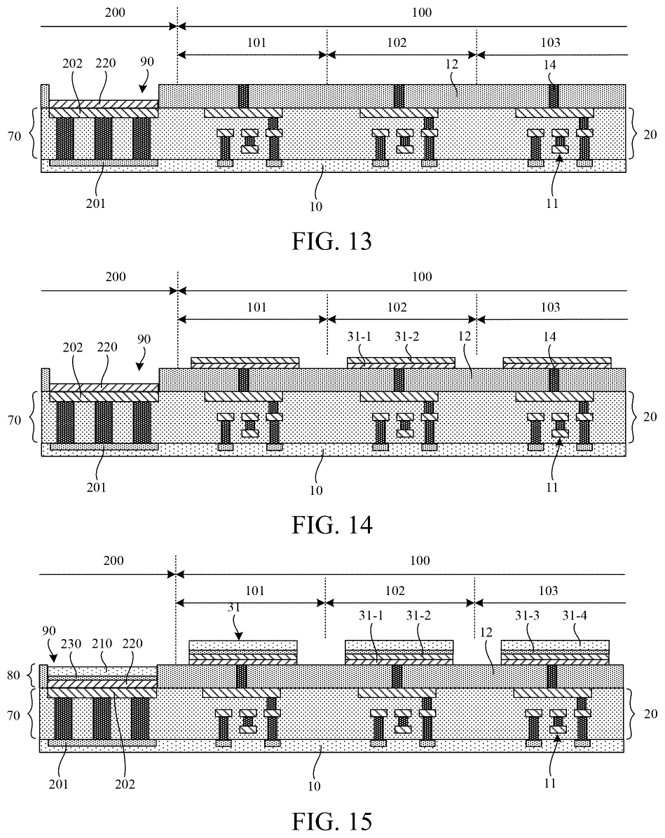

In an exemplary implementation, the material of the composite insulating layer 12 may be silicon oxide SiOx.
(4) A pattern of an anode conductive post is formed. In an exemplary implementation, forming the pattern of the anode conductive post may include: forming a plurality of anode conductive posts 14 in a plurality of connection vias 13 respectively on the base substrate on which the above patterns are formed, wherein the anode conductive post 14 is connected to the anode connection electrode, as shown in FIG. 13.

In an exemplary implementation, the anode conductive post 14 is configured to connect an anode formed subsequently to achieve connection between the anode and the pixel drive circuit. The anode conductive post 14 may be made of a metal material and formed by a treatment of filling. For example, the anode conductive post 14 may be made of metal tungsten (W), and a via filled with tungsten metal is referred to as a tungsten via (W-via). The usage of the tungsten vias may guarantee the stability of a conductive pathway. Due to the maturity of the process of preparing the tungsten vias, the flatness of the surface of the formed composite insulating layer 12 is good, which is beneficial to decrease in contact resistance.

In an exemplary implementation, after the anode conductive post 14 is formed by the treatment of filling, surfaces of the composite insulating layer 12 and the anode conductive post 14 may be treated by a chemical mechanical polishing (CMP) process to remove a portion of the thickness of the composite insulating layer 12 and a portion of the thickness of the anode conductive post 14, so that the composite insulating layer 12 and the anode conductive post 14 form a flush surface.

After this patterning process, the film layer structure of the bonding area 200 do not change.
(5) Patterns of a first anode layer and a second anode layer are formed. In an exemplary implementation, forming the patterns of the first anode layer and the second anode layer may include: sequentially depositing a first anode thin film and a second anode thin film on the base substrate on which the above patterns are formed, and patterning the first anode thin film and the second anode thin film by a patterning process, to form a plurality of stacked first anode layers 31-1 and second anode layers 31-2 on the composite insulating layer 12 in the display area 100, as shown in FIG. 14.

In an exemplary implementation, the plurality of stacked first anode layers 31-1 and second anode layers 31-2 in the display area 100 may be respectively located in each sub-pixel, the first anode layer 31-1 is disposed on a side of the composite insulating layer 12 away from the base substrate 10 and connected to the anode connection electrode through the anode conductive post 14 in the connection via 13, and the second anode layer 31-2 is disposed on a side of the first anode layer 31-1 away from the base substrate 10.

In an exemplary implementation, the material of the first anode layer 31-1 may be metal titanium (Ti), and the material of the second anode layer 31-2 may be metal aluminum (Al).

After this patterning process, the film layer structure of the bonding area 200 do not change.
(6) Patterns of a third anode layer, a fourth anode layer, a third bonding pad layer and a first bonding pad layer are formed. In an exemplary implementation, forming the patterns of the third anode layer, the fourth anode layer, the third bonding pad layer and the first bonding pad layer may include: on the base substrate on which the above patterns are formed, first forming a third anode thin film, then depositing a fourth anode thin film, and patterning the third anode thin film and the fourth anode thin film by a patterning process, forming a plurality of stacked third anode layers 31-3 and fourth anode layers 31-4 on the second anode layer 31-2 in the display area 100, and forming a plurality of stacked third bonding pad layers 230 and first bonding pad layers 210 on the second bonding pad layer 220 in the bonding area 200, as shown in FIG. 15.

In an exemplary implementation, the plurality of stacked third anode layers 31-3 and fourth anode layers 31-4 in the display area 100 may be respectively located in each sub-pixel., The third anode layer 31-3 is disposed on a side of the second anode layer 31-2 away from the base substrate 10, and the fourth anode layer 31-4 is disposed on a side of the third anode layer 31-3 away from the base substrate 10.

In an exemplary implementation, the stacked first anode layer 31-1, second anode layer 31-2, third anode layer 31-3 and fourth anode layer 31-4 form an anode 31, and the anode 31 is connected to the anode connection electrode of the pixel drive circuit through the anode conductive post 14.

In an exemplary implementation, the first bonding pad layer 210 and the third bonding pad layer 230 in the bonding area 200 may be disposed in the pad groove 90, the third bonding pad layer 230 is disposed on a side of the second bonding pad layer 220 away from the base substrate 10, and the first bonding pad layer 210 is disposed on a side of the third bonding pad layer 230 away from the base substrate 10.

In an exemplary implementation, the stacked second bonding pad layer 220, third bonding pad layer 230 and first bonding pad layer 210 form a bonding pad 80 configured to be bonded to connect to an external circuit board.

In an exemplary implementation, the material of the third anode thin film may be titanium nitride (TiN). Titanium nitride has the characteristics of high thermal hardness, good toughness, good chemical stability, excellent corrosion and oxidation resistance, etc. The third bonding pad layer 230 formed of the material of titanium nitride covers the second bonding pad layer 220, which, on the one hand, can protect the second bonding pad layer 220 from the corrosion caused by the reaction of Cl₂ or Cl ion residues in an etching solution with the second bonding pad layer 220 in the patterning process, and on the other hand, can serve as a barrier layer to prevent the mutual reaction and diffusion between the second bonding pad layer 220 and the first bonding pad layer 210 under high temperature environment and avoid contact failure caused by increased resistivity of the second bonding pad layer 220.

In an exemplary implementation, the material of the fourth anode thin film may be indium tin oxide (ITO). Indium tin oxide has the characteristics of weak reducibility, low conductivity, easy surface treatment, etc. The first bonding pad layer 210 formed by the material of indium tin oxide, on the one hand, can further protect the second bonding pad layer 220 by covering the third bonding pad layer 230, and avoid the increase of the impedance caused by the corrosion of the bonding pad and improve the reliability of bonding connection, and on the other hand, can increase the contact area of the bonding connection and reduce the bonding impedance and further improve the reliability of the bonding connection, by forming a rough surface.

In an exemplary implementation, the anode 31 of the display area 100 may include a first anode layer 31-1, a second anode layer 31-2, a third anode layer 31-3 and a fourth anode layer 31-4 which are stacked, and the conductivity of the first anode layer 31-1 and the second anode layer 31-2 may be greater than that of the third anode layer 31-3 and the fourth anode layer 31-4, so as to effectively reduce the overall impedance of the anode 31 and effectively reduce the voltage drop of the anode 31.

In an exemplary implementation, the third bonding pad layer 230 of the bonding area 200 and the third anode layer 31-3 of the display area 100 are disposed in a same layer and formed synchronously by a same patterning process, and the first bonding pad layer 210 of the bonding area 200 and the fourth anode layer 31-4 of the display area 100 are disposed in a same layer and formed synchronously by a same patterning process.

In an exemplary implementation, in the patterning process, part of the thickness of the fourth anode layer 31-4 in the display area may be etched so that the thickness of the fourth anode layer 31-4 is smaller than the thickness of the first bonding pad layer 210, which can reduce the impedance and voltage drop of the anode 31 in the display area 100 on the one hand, and can ensure that the first bonding pad layer 210 in the bonding area 200 protects the third bonding pad layer 230 on the other hand.

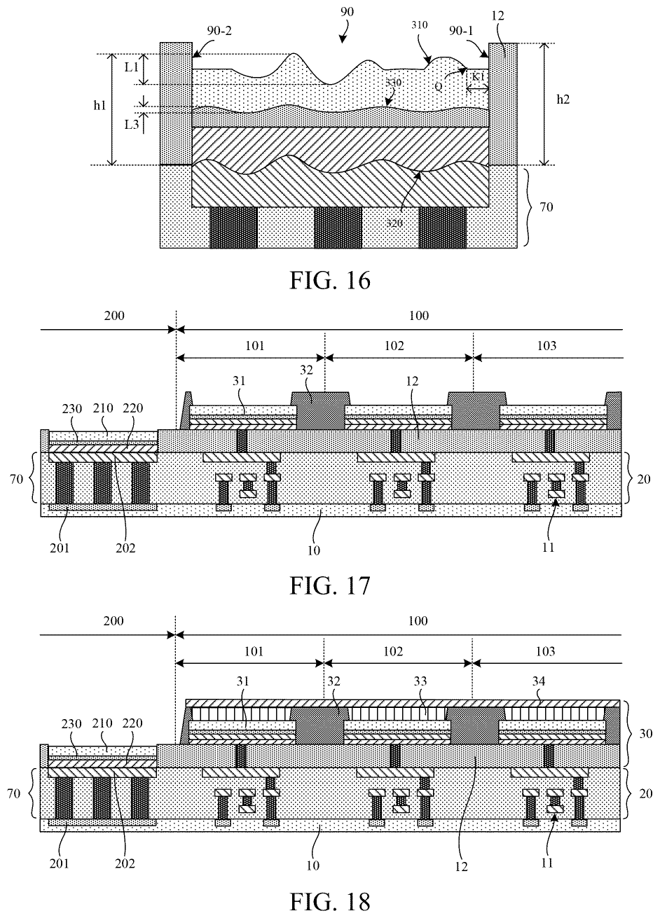

FIG. 16 is a schematic diagram of a structure of a first bonding pad layer according to an exemplary embodiment of the present disclosure. As shown in FIG. 16, the bonding pad in the bonding area 200 is disposed in the pad groove 90, including a second bonding pad layer 220, a third bonding pad layer 230 and a first bonding pad layer 210 which are stacked. The second bonding pad layer 220 is disposed on a side of the second bonding electrode 202 away from the base substrate, the third bonding pad layer 230 is disposed on a side of the second bonding pad layer 220 away from the base substrate, and the first bonding pad layer 210 is disposed on a side of the third bonding pad layer 230 away from the base substrate.

In an exemplary implementation, the third bonding pad layer 230 made of the material of titanium nitride is disposed between the first bonding pad layer 210 and the second bonding pad layer 220, and the third bonding pad layer 230 may function to protect the second bonding pad layer 220 from corrosion caused by the reaction of Cl₂ or Cl ion residues in an etching solution with the second bonding pad layer 220 in the patterning process. For the usage of indium tin oxide to the first bonding pad layer 210 and aluminum to the second bonding pad layer 220, since indium tin oxide is a metal oxide, reaction will occur when it directly contacts the active metal aluminum, to generate an aluminum compound, which seriously affects the overall conductivity of the bonding pad. In the present disclosure, the third bonding pad layer 230 may serve as a barrier layer to prevent mutual reaction and diffusion between the second bonding pad layer 220 and the first bonding pad layer 210 under a high temperature environment, to avoid an increase in the resistivity of the second bonding pad layer 220 and avoid contact failure.

In an exemplary implementation, the conductivity of the first bonding pad layer 210 may be less than that of the second bonding pad layer 220, and the reducibility of the first bonding pad layer 210 may be less than that of the second bonding pad layer 220. In the present disclosure, by arranging the relationships in conductivity and reducibility between the first bonding pad layer 210 and the second bonding pad layer 220, the first bonding pad layer 210 can protect the second bonding pad layer 220, which can prevent the surface of the first bonding pad layer 210 from being oxidized, prevent the impedance from being increased due to the corrosion of the first bonding pad layer 210, and improve the reliability of bonding connection.

In an exemplary implementation, the conductivity of the third bonding pad layer 230 may be less than that of the first bonding pad layer 210, and the reducibility of the third bonding pad layer 230 may be less than that of the first bonding pad layer 210. In the present disclosure, by disposing the third bonding pad layer 230, which has less conductivity and less reducibility, between the first bonding pad layer 210 and the second bonding pad layer 220, the third bonding pad layer 230 can protect the second bonding pad layer 220 from corrosion caused by the reaction of Cl₂ or Cl ion residues in an etching solution with the second bonding pad layer 220 in the patterning process.

In an exemplary implementation, the thickness of the first bonding pad layer 210 may be greater than the thickness of the second bonding pad layer 220, the thickness of the third bonding pad layer 230 may be less than or equal to 0.2*the thickness of the first bonding pad layer 210, and the thickness of the third bonding pad layer 230 may be less than or equal to 0.2*the thickness of the second bonding pad layer 220, i.e., the thickness of the first bonding pad layer 210 and the second bonding pad layer 220 may be greater than 5 times the thickness of the third bonding pad layer 230. In the present disclosure, by arranging the relationship in thickness among the first bonding pad layer 210, the second bonding pad layer 220 and the third bonding pad layer 230, it can be ensured that the third bonding pad layer 230 completely separates the first bonding pad layer 210 from the second bonding pad layer 220, so that the third bonding pad layer 230 completely covers and protects the second bonding pad layer 220, thus improving the protection effect.

In an exemplary implementation, the surface roughness of the surface of the side of the first bonding pad layer 210 away from the base substrate may be greater than the surface roughness of the surface of the side of the second bonding pad layer 220 away from the base substrate, and the surface roughness of the surface of the side of the first bonding pad layer 210 away from the base substrate may be greater than the surface roughness of the surface of the side of the third bonding pad layer 230 away from the base substrate. In the present disclosure, by arranging relatively larger surface roughness of the first bonding pad layer 210, it is beneficial to increasing the contact area between the first bonding pad layer 210 and the conductive auric balls and the solvent in the anisotropic conductive film, enhancing the adhesion strength and reducing bonding impedance, which can improve the reliability of bonding connection.

In an exemplary implementation, at least one first concave-convex structure 310 is formed on the surface of the side of the first bonding pad layer 210 away from the base substrate. The first concave-convex structure 310 may include at least one first protrusion and at least one first groove. In the present disclosure, by forming the first concave-convex structure 310 on the surface of the first bonding pad layer 210, the contact area between the first bonding pad layer 210 and the gold finger in the circuit board can be increased, the bonding adhesion area can be increased, and the bonding impedance can be reduced, thus improving the reliability of bonding connection.

In an exemplary implementation, the first concave-convex structure may be only a plurality of first protrusions provided on a flat surface, the first protrusions are higher than the flat surface, i.e., the thicknesses at the first protrusions are greater than the thickness of the flat surface, and which are between adjacent first protrusions are considered as first grooves. In another exemplary implementation, the first concave-convex structure may be only a plurality of first grooves provided on a flat surface, the first grooves are lower than the flat surface, i.e., the thicknesses at the first grooves are less than the thickness of the flat surface, and which are between adjacent first grooves are considered as first protrusions. In yet another exemplary implementation, the first concave-convex structure may be a plurality of first protrusions and a plurality of first grooves provided on a flat surface, the first protrusions are higher than the flat surface, and the first grooves are lower than the flat surface.

In an exemplary implementation, there is a first distance L1 between the highest first top of the plurality of first protrusions on a side away from the base substrate and the lowest first bottom of the plurality of first grooves on a side close to the base substrate, and the first distance L1 may be less than or equal to 0.5*the average thickness of the first bonding pad layer 210. In the present disclosure, by arranging the maximum distance between the protrusion and the groove in the first concave-convex structure 310, it can be ensured that the first bonding pad layer 210 completely covers and protects the second bonding pad layer 220, improving the protection reliability to the greatest extent.

In an exemplary implementation, the first distance L1 may be greater than the second distance L2.

In an exemplary implementation, there is a first height h1 between the highest first top of the plurality of first protrusions on a side away from the base substrate and a surface of a side of the composite insulating layer 12 close to the base substrate, there is a second height h2 between a surface of a side of the composite insulating layer 12 away from the base substrate and the surface of the side of the composite insulating layer 12 close to the base substrate, and the first height h1 may be less than the second height h2. In the present disclosure, by arranging the highest point of the first bonding pad layer 210 lower than the upper surface of the composite insulating layer 12, during photoresist spin coating of the patterning process, the photoresist can be prevented from touching the protrusion higher than the composite insulating layer 12, and the occurrence of mura in the display area due to the generation of reflux ripple can be avoided.

In an exemplary implementation, the pad groove 90 may include a first sidewall 90-1 on a side close to the display area 100 and a second sidewall 90-2 on a side away from the display area 100. There is a first junction line between the first protrusion close to the first sidewall 90-1 and the surface of the side of the first bonding pad layer 210 away from the base substrate, the first junction line includes a junction point Q on a side close to the display area, there is a first length K1 between the junction point Q and the first sidewall 90-1, the first length K1 may be greater than or equal to 0, and the first length K1 may be less than or equal to a difference between the second height h2 and the first height h1, the difference between the second height h2 and the first height h1 is the distance between the top of the first protrusion and the upper surface of the composite insulating layer 12. In the present disclosure, by arranging the position of the first concave-convex structure in the pad groove, during photoresist spin coating of the patterning process, the generation of reflux ripple, due to the contact of the photoresist with the convex apex of the first concave-convex structure, can be prevented, the occurrence of mura in the display area can be avoided, at the same time the contact area between the first bonding pad layer 210 and the gold finger in the circuit board can be increased, the bonding adhesion area can be increased, and the bonding impedance can be reduced, thus improving the reliability of bonding connection.

In an exemplary implementation, the surface of the side of the third bonding pad layer 230 away from the base substrate is formed with at least one third concave-convex 330 which may include at least one third protrusion and at least one third groove. In the present disclosure, by forming the third concave-convex structure 330 on the surface of the third bonding pad layer 230, on the one hand, it can be ensured that the third bonding pad layer 230 completely separates the first bonding pad layer 210 from the second bonding pad layer 220, and on the other hand, the contact area between the third bonding pad layer 210 and the first bonding pad layer 210 can be increased, and connection impedance can be reduced.

In an exemplary implementation, the third concave-convex structure may be only a plurality of third protrusions provided on a flat surface, the third protrusions are higher than the flat surface, i.e., the thicknesses at the third protrusions are greater than the thickness of the flat surface, and which are between adjacent third protrusions are considered as third grooves. In another exemplary implementation, the third concave-convex structure may be only a plurality of third grooves provided on a flat surface, the third grooves are lower than the flat surface, i.e., the thicknesses at the third grooves are less than the thickness of the flat surface, and which are between adjacent third grooves are considered as third protrusions. In yet another exemplary implementation, the third concave-convex structure may be a plurality of third protrusions and a plurality of third grooves provided on a flat surface, the third protrusions are higher than the flat surface, and the third grooves are lower than the flat surface.

In an exemplary implementation, there is a third distance L3 between the highest third top of the plurality of third protrusions on a side away from the base substrate and the lowest third bottom of the plurality of third grooves on a side close to the base substrate, and the third distance L3 may be less than the first distance L1.

In an exemplary implementation, the surface of the side of the first bonding pad layer 210 close to the base substrate is attached to the surface of the side of the third bonding pad layer 230 away from the base substrate, and the surface of the side of the third bonding pad layer 230 away from the base substrate is formed with at least one third concave-convex structure 330, thereby, the surface of the side of the first bonding pad layer 210 close to the base substrate is a concave-convex structure having a shape complementary to that of the third concave-convex structure 330.
(7) A pattern of a pixel definition layer is formed. In an exemplary implementation, forming the pattern of the pixel definition layer may include: coating a pixel definition thin film on the base substrate on which the above structures are formed, and forming a pattern of a pixel definition layer (PDL) 32 by masking, exposure and development process. The pixel definition layer 32 is formed in the display area 100, and the pixel definition layer 32 of each sub-pixel is provided with a pixel opening that exposes the anode 31 of each sub-pixel, as shown in FIG. 17.

After this patterning process, the film layer structure of the bonding area 200 do not change.
(8) Patterns of an organic light emitting layer and a cathode are formed. In an exemplary implementation, forming the patterns of the organic light emitting layer and the cathode may include: sequentially forming an organic light emitting layer 33 and a cathode 34 on the base substrate on which the above structures are formed. The organic light emitting layer 33 is formed in each sub-pixel in the display area 100, and the organic light emitting layer 33 is connected to the anode 31 of the sub-pixel in which the organic light emitting layer 33 is located through a pixel opening. The planar cathode 34 is formed in the display area 100, and the cathode 34 is connected to the organic light emitting layer 33 of each sub-pixel, as shown in FIG. 18.

In an exemplary implementation, the organic light emitting layer 33 may include a first light emitting sub-layer, a second light emitting sub-layer and a third light emitting sub-layer which are stacked. The first light emitting sub-layer is configured to emit light of a first color, the second light emitting sub-layer is configured to emit light of a second color, and the third light emitting sub-layer is configured to emit light of a third color. Therefore, the organic light emitting layer finally emits mixed light. For example, it may be disposed that the first emitting material layer is a red light material layer emitting red light, the second emitting material layer is a green light material layer emitting green light, and the third emitting material layer is a blue light material layer emitting blue light, and thus the organic light emitting layer eventually emits white light.

Hereto, preparation of the light emitting structure layer 30 of the display area 100 is completed. In an exemplary implementation, the light emitting structure layer 30 of each sub-pixel may include a composite insulating layer 12 disposed on the drive structure layer, a light emitting device disposed on the composite insulating layer 12, and a pixel definition layer 32, and the light emitting device may include an anode 31, an organic light emitting layer 33 and a cathode 34.

After this patterning process, the film layer structure of the bonding area 200 do not change.
(9) An encapsulation structure layer, a color filter structure layer and a cover plate structure layer are formed sequentially. In an exemplary implementation, sequentially forming the encapsulation structure layer, the color filter structure layer and the cover plate structure layer may include: forming a pattern of an encapsulation structure layer 40 on the base substrate on which the above structures are formed. The encapsulation structure layer 40 is formed in the display area 100. In an exemplary implementation, the encapsulation structure layer 40 may include a plurality of film layers, such as a first encapsulation layer of inorganic material and a second encapsulation layer of organic material, or a first encapsulation layer of inorganic material, a second encapsulation layer of organic material and a third encapsulation layer of inorganic material. The inorganic material may be formed by chemical vapor deposition (CVD), plasma enhanced chemical vapor deposition (PECVD), atomic layer deposition (ALD) or molecular layer deposition (MLD) equipment. Subsequently, a pattern of a color filter structure layer 50 is formed on the base substrate on which the above structures are formed. The color filter structure layer 50 is formed in the display area 100. The color filter structure layer 50 may include a first color unit, a second color unit and a third color unit corresponding to sub-pixels. The color units in the color filter structure layer 50 may overlap each other as a black matrix, or a black matrix may be provided between the color units. Subsequently, a cover plate structure layer 60 is formed by a sealing process. The cover plate structure layer 60 may be arranged in the display area 100. The cover plate structure layer 60 may be fixed by sealant, and the base substrate 10, the cover plate structure layer 60 and the sealant form a closed space together, which additionally provides guarantee of blocking water and oxygen, and greatly prolongs the service life of the silicon-based OLED display substrate, as shown in FIG. 6.

So far, the preparation of the display substrate according to an exemplary embodiment of the present disclosure is completed. In an exemplary implementation, film layers such as a second encapsulation layer and an adhesive layer (OCA) may also be provided between the color filter structure layer 50 and the cover plate structure layer 60, which is not limited here in the present disclosure.

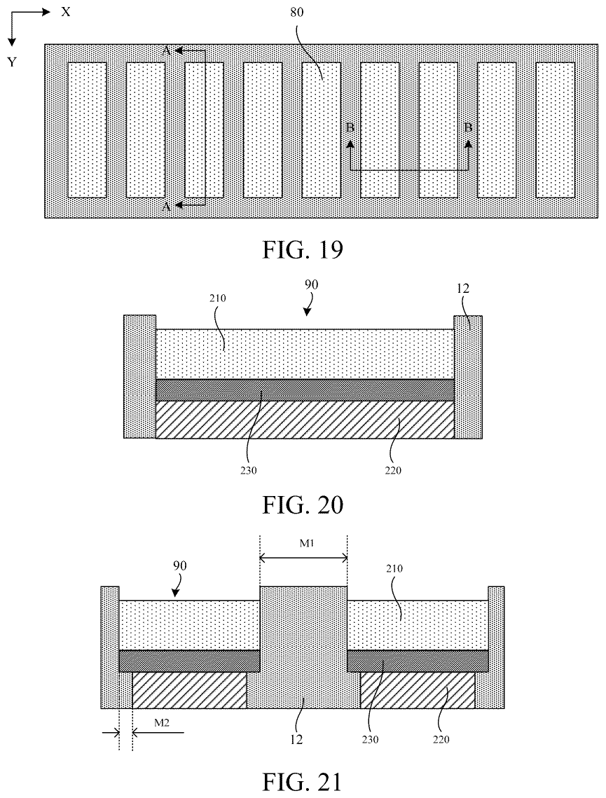

FIG. 19 is a schematic diagram of a planar structure of a bonding pad in a bonding area of a display substrate of the present disclosure. As shown in FIG. 19, a plurality of bonding pads 80 may be spaced in a first direction X, and each bonding pad 80 may be in a shape of a strip extending in a second direction Y. The first direction X crosses the second direction Y, and the second direction Y may be a direction away from the display area.

FIG. 20 is a sectional view taken in an A-A direction in FIG. 19, and FIG. 21 is a sectional view taken in a B-B direction in FIG. 19. As shown in FIGS. 20 and 21, the bonding pad 80 including stacked second bonding pad layer 220, third bonding pad layer 230 and first bonding pad layer 210 is disposed in the pad groove 90 provided on the composite insulating layer 12. The second bonding pad layer 220 is disposed on a side of the bonding structure layer 70 away from the base substrate and lapped with the second bonding electrode, the third bonding pad layer 230 is disposed on a side of the second bonding pad layer 220 away from the base substrate and lapped with the second bonding pad layer 220, and the first bonding pad layer 210 is disposed on a side of the third bonding pad layer 230 away from the base substrate and lapped with the third bonding pad layer 230.

In an exemplary implementation, in the second direction Y, the first bonding pad layer 210, the second bonding pad layer 220 and the third bonding pad layer 230 have substantially a same extension length, and orthographic projections of two ends of the first bonding pad layer 210, two ends of the second bonding pad layer 220 and two ends of the third bonding pad layer 230 in the second direction Y on the base substrate may substantially overlap.

In an exemplary implementation, in the first direction X, the first bonding pad layer 210 and the third bonding pad layer 230 have a same width, the width of the first bonding pad layer 210 is greater than the width of the second bonding pad layer 220, the width is the size in the first direction X, and orthographic projections of the first bonding pad layer 210 and the third bonding pad layer 230 on the base substrate include an orthographic projection of the second bonding pad layer 220 on the base substrate.

In an exemplary implementation, a first spacing M1 between two adjacent first bonding pad layers 210 in the first direction X may be greater than or equal to 30 μm. In at least one bonding pad, a second spacing M2 between an edge of the first bonding pad layer 210 and an edge of the second bonding pad layer 220 may be greater than or equal to 0.3 μm.

As can be seen from the structure of the display substrate and the preparation process thereof in the present disclosure, the present disclosure improves the bonding reliability to the maximum extent, by arranging the bonding pad including stacked second bonding pad layer, third bonding pad layer and first bonding pad layer. In the present disclosure, the first bonding pad layer formed by indium tin oxide is used and the surface of the first bonding pad layer is formed with a first concave-convex structure, which, on the one hand, can protect the second bonding pad layer, avoid the increase in impedance caused by the corrosion of the bonding pad and improve the reliability of bonding connection, and on the other hand, can increase the contact area of bonding connection, reduce the bonding impedance, and further improve the reliability of bonding connection, by forming a rough surface. In the present disclosure, the third bonding pad layer of titanium nitride material is arranged between the first bonding pad layer and the second bonding pad layer. On the one hand, the third bonding pad layer can protect the second bonding pad layer, and avoid corrosion caused by the reaction between Cl₂ or Cl ion residues in an etching solution with the second bonding pad layer in the patterning process. On the other hand, the third bonding pad layer can be used as a barrier layer to prevent mutual reaction and diffusion between the second bonding pad layer and the first bonding pad layer under a high temperature environment, avoid an increase in resistivity of the second bonding pad layer, and avoid contact failure. The present disclosure effectively solves the problem that the existing silicon-based OLED display substrates have poor bonding reliability due to corrosion of bonding pads, improves the bonding reliability to the maximum extent, reduces the failure risk of products and improves the working reliability of products. The preparation process of the present disclosure can be achieved by using mature preparation equipment, and has small improvements in process, high compatibility, simple process flow, high production efficiency, low production cost and high yield, and therefore has a good application prospect.

A structure of the display device and the preparation process thereof according to exemplary embodiments of the present disclosure are described by way of examples only. Corresponding structures may be changed and patterning processes may be added or reduced according to actual needs, the present disclosure is not limited thereto.

An exemplary embodiment of the present disclosure also provides a method for preparing a display substrate to prepare the aforementioned display substrate. In an exemplary implementation, the method may include: forming a bonding structure layer on a base substrate; and forming a bonding pad on the bonding structure layer, wherein the bonding pad is configured to be bonded to connect to a circuit board; the bonding pad at least includes a first bonding pad layer and a second bonding pad layer, the first bonding pad layer is disposed on a side of the second bonding pad layer away from the base substrate, and at least one first concave-convex structure is disposed on a surface of a side of the first bonding pad layer away from the base substrate.

The present disclosure further provides a display device which includes the display substrate describe above. The display device may be a virtual reality device, an augmented reality device or a near-to-eye display device, or may be a mobile phone, a tablet computer, a television, a display, a notebook computer, a digital photo frame or a navigator, or any other product or component with a display function.

Although the implementations of the present disclosure are disclosed above, the contents are only implementations adopted to easily understand the present disclosure and not intended to limit the present disclosure. Any skilled person in the art to which the present disclosure pertains may make any modification and alteration in forms and details of implementation without departing from the spirit and scope of the present disclosure. However, the scope of patent protection of the present disclosure should be subject to the scope defined by the appended claims.

1. A display substrate, comprising a display area, and a bonding area located on a side of the display area, wherein on a plane perpendicular to the display substrate, the bonding area comprises a base substrate, a bonding structure layer disposed on the base substrate, and a bonding pad disposed on a side of the bonding structure layer away from the base substrate, the bonding pad is configured to be bonded to connect to a circuit board; the bonding pad at least comprises a first bonding pad layer and a second bonding pad layer, the first bonding pad layer is disposed on a side of the second bonding pad layer away from the base substrate, and at least one first concave-convex structure is disposed on a surface of a side of the first bonding pad layer away from the base substrate.

2. The display substrate according to claim 1, wherein a reducibility of the first bonding pad layer is less than that of the second bonding pad layer.

3. The display substrate according to claim 1, wherein a conductivity of the first bonding pad layer is less than that of the second bonding pad layer.

4. The display substrate according to claim 1, wherein a surface roughness of a surface of a side of the first bonding pad layer away from the base substrate is greater than that of a surface of a side of the second bonding pad layer away from the base substrate.

5. The display substrate according to claim 1, wherein a thickness of the first bonding pad layer is greater than that of the second bonding pad layer.

6. The display substrate according to claim 1, wherein the first concave-convex structure comprises at least one first protrusion and at least one first groove, there is a first distance between a first top on a side of the first protrusion away from the base substrate and a first bottom on a side of the first groove close to the base substrate, and the first distance is less than or equal to 0.5*a thickness of the first bonding pad layer.

7. The display substrate according to claim 1, wherein the bonding area further comprises a composite insulating layer disposed on a side of the bonding structure layer away from the base substrate, at least one pad groove is disposed on the composite insulating layer, and the first bonding pad layer and the second bonding pad layer are disposed in the pad groove.

8. The display substrate according to claim 7, wherein the first concave-convex structure comprises at least one first protrusion, there is a first height between a first top on a side of the first protrusion away from the base substrate and a surface of a side of the composite insulating layer close to the base substrate, and there is a second height between a surface of a side of the composite insulating layer away from the base substrate and the surface of the side of the composite insulating layer close to the base substrate, and the first height is less than the second height.

9. The display substrate according to claim 8, wherein there is a first junction line between the first protrusion and a surface of a side of the first bonding pad layer away from the base substrate, the first junction line comprises a junction point close to a side of the display area, and there is a first length between the junction point and a first sidewall, the first length is greater than or equal to 0.

10. The display substrate according to claim 9, wherein the first length is less than or equal to a difference between the second height and the first height.

11. The display substrate according to claim 1, wherein the bonding pad further comprises a third bonding pad layer disposed between the first bonding pad layer and the second bonding pad layer, a conductivity of the third bonding pad layer is less than that of the first bonding pad layer, and a reducibility of the third bonding pad layer is less than that of the first bonding pad layer.

12. The display substrate according to claim 11, wherein a thickness of the third bonding pad layer is less than or equal to 0.2*a thickness of the first bonding pad layer, and the thickness of the third bonding pad layer is less than or equal to 0.2*a thickness of the second bonding pad layer.

13. The display substrate according to claim 11, wherein a surface roughness of a surface of a side of the third bonding pad layer away from the base substrate is less than that of a surface of a side of the first bonding pad layer away from the base substrate; or
a surface roughness of a surface of a side of the third bonding pad layer away from the base substrate is less than that of a surface of a side of the second bonding pad layer close to the base substrate.

14. (canceled)

15. The display substrate according to claim 11, wherein at least one third concave-convex structure is disposed on a surface of a side of the third bonding pad layer away from the base substrate.

16. The display substrate according to claim 15, wherein the first concave-convex structure comprises at least one first protrusion and at least one first groove, there is a first distance between a first top on a side of the first protrusion away from the base substrate and a first bottom on a side of the first groove close to the base substrate; the third concave-convex structure comprises at least one third protrusion and at least one third groove, and there is a third distance between a third top on a side of the third protrusion away from the base substrate and a third bottom on a side of the third groove close to the base substrate; and the third distance is less than the first distance.

17. The display substrate according to claim 16, wherein at least one second concave-convex structure is disposed on a surface of a side of the second bonding pad layer close to the base substrate, the second concave-convex structure comprises at least one second protrusion and at least one second groove, and there is a second distance between a second top on a side of the second protrusion close to the base substrate and a second bottom on a side of the second groove away from the base substrate; and the second distance is less than the first distance.

18. The display substrate according to claim 1, wherein the display area comprises a base substrate, a drive structure layer disposed on the base substrate, and a light emitting structure layer disposed on a side of the drive structure layer away from the base substrate; the light emitting structure layer at least comprises an anode, the anode comprises a first anode layer, a second anode layer disposed on a side of the first anode layer away from the base substrate, a third anode layer disposed on a side of the second anode layer away from the base substrate, and a fourth anode layer disposed on a side of the third anode layer away from the base substrate, the first bonding pad layer in the bonding pad is disposed in a same layer as the fourth anode layer, and the third bonding pad layer in the bonding pad is disposed in a same layer as the third anode layer.

19. The display substrate according to claim 18, wherein a thickness of the fourth anode layer is less than that of the first bonding pad layer.

20. A display device, comprising the display substrate according to claim 1.

21. A method for preparing a display substrate, the display substrate comprising a display area and a bonding area located on a side of the display area, the method comprising:
forming a bonding structure layer on a base substrate; and
forming a bonding pad on the bonding structure layer, wherein the bonding pad is configured to be bonded to connect to a circuit board; the bonding pad at least comprises a first bonding pad layer and a second bonding pad layer, the first bonding pad layer is disposed on a side of the second bonding pad layer away from the base substrate, and at least one first concave-convex structure is disposed on a surface of a side of the first bonding pad layer away from the base substrate.
